(19) United States
(12) Patent Application Publication
(10) Pub. No.: US 2013/0056063 A1
(43) Pub. Date: Mar. 7, 2013

(54) PREPARATION METHOD OF OXIDE ELECTRODE FOR SENSITIZED SOLAR CELL AND SENSITIZED SOLAR CELL USING THE SAME

(71) Applicants: Kyung-Kon KIM, Seoul (KR); Nam-Gyu PARK, Seoul (KR); Dong-Young KIM, Seoul (KR); Jun-Kyung KIM, Seoul (KR)

(72) Inventors: Kyung-Kon KIM, Seoul (KR); Nam-Gyu PARK, Seoul (KR); Dong-Young KIM, Seoul (KR); Jun-Kyung KIM, Seoul (KR)

(21) Appl. No.: 13/667,670

(22) Filed: Nov. 2, 2012

Related U.S. Application Data
(63) Continuation-in-part of application No. 12/446,837, filed on Apr. 23, 2009.

(30) Foreign Application Priority Data
Oct. 24, 2006 (KR) 10-2006-0103440

(51) Int. Cl. B05D 5/12; H01L 31/0224

(52) U.S. Cl. 136/256; 427/74

(57) ABSTRACT

The present invention relates to a method of manufacturing an oxide electrode for a dye-sensitized solar cell including metal oxide nanoparticles by using a miller, and a dye-sensitized solar cell manufactured by using the same. More particularly, the present invention provides a method of manufacturing an oxide electrode for a dye-sensitized solar cell. The method includes (a) mixing metal oxide nanoparticles, a binder resin, and a solvent to prepare a metal oxide paste, (b) coating the metal oxide paste to a miller and pulverizing the metal oxide nanoparticles to prepare a paste including the metal oxide nanoparticles uniformly dispersed therein, and (c) coating the paste including the metal oxide nanoparticles dispersed therein on a conductive transparent substrate, performing a heat treatment of the resulting substrate, and adsorbing a dye thereon to manufacture the conductive electrode.

### CROSS REFERENCE TO RELATED APPLICATIONS

This is a continuation-in-part of U.S. patent application Ser. No. 12/446,837, filed Apr. 23, 2009, which is a national stage entry of PCT/KR2006/005346, filed Dec. 8, 2006, claiming priority from Korean Application No. 10-2006-0103440, filed Oct. 24, 2006. The entire disclosures of the prior applications are considered part of the disclosure of the accompanying continuation application, and are hereby incorporated by reference.

### BACKGROUND OF THE INVENTION

(a) Field of the Invention

The present invention relates to a dye-sensitized solar cell using a metal oxide nanoparticle paste and a method of manufacturing the same. More particularly, the present invention relates to a method of pulverizing metal oxide nanoparticles that are essential materials of a dye-sensitized solar cell and uniformly dispersing the nanoparticles in a paste to improve efficiency of the solar cell.

(b) Description of the Related Art

A dye-sensitized solar cell is a photoelectrochemical solar cell which is suggested by Gratzel et al. in Switzerland in the year 1991, and comes into the spotlight as the next generation solar cell that is capable of being used instead of a known silicone solar cell because of its low manufacturing cost.

The dye-sensitized solar cell includes a conductive electrode (first electrode) formed of metal oxide nanoparticles on which dye molecules are adsorbed, a counter electrode (second electrode) on which platinum or carbon is coated, and iodine-based oxidation and reduction electrolytes.

In general, the conductive electrode of the dye-sensitized solar cell is formed on a glass substrate by using the titanium oxide nanoparticles according to the following procedure.

Specifically, after a colloidal solution of titanium oxide nanoparticles is prepared, a polymer is mixed with the colloidal solution of titanium oxide to prepare a titanium oxide paste having high viscosity.

Subsequently, the titanium oxide paste having the high viscosity is coated on a transparent conductive glass substrate and subjected to heat treatment in an air or oxygen atmosphere at a high temperature in the range of 450 to 500° C. for about 30 minutes to form a nanoparticle titanium oxide electrode.

During the heat treatment, the metal oxide nanoparticles are partially bonded to each other to have a nanopore structure. The nanopore structure is significantly affected by the dispersion of the metal oxide paste and affects characteristics of the dye-sensitized solar cell.

The dispersed metal oxide colloidal solution and the polymer material used as the binder are mixed with each other, and a solvent is then removed to prepare the metal oxide nanoparticle paste.

Examples of known methods of dispersing the metal oxide colloidal solution include an ultrasonic wave dispersion method, a bead mill dispersion method, and the like.

However, when the above-mentioned methods are used, the metal oxide nanoparticles may be agglomerated in the paste after the paste is prepared. In connection with this, a method of re-dispersing the agglomerated nanoparticles has not yet been developed.

### SUMMARY OF THE INVENTION

To resolve the problem of the related art, an object of the present invention is to provide a method of manufacturing an oxide electrode for a dye-sensitized solar cell including metal oxide nanoparticles prepared by using a 3-roll miller, and a dye-sensitized solar cell manufactured by using the same. In the method, a metal oxide nanoparticle paste is prepared and uniformly dispersed according to a pulverizing process using a miller that is capable of uniformly re-dispersing the nanoparticles contained in the paste to form a metal oxide nanoparticle structure having uniform nanopores, so that when the oxide electrode is used in the dye-sensitized solar cell, efficiency is improved.

### BRIEF DESCRIPTION OF THE DRAWINGS

FIG. 1 is a schematic cross-sectional view of a 3-roll miller according to an exemplary embodiment of the present invention;

FIG. 2 is a view schematically illustrating dispersion of a metal oxide nanoparticle paste by using the 3-roll miller according to an exemplary embodiment of the present invention;

FIG. 3 is a cross-sectional view schematically illustrating a configuration of a dye-sensitized solar cell according to an exemplary embodiment of the present invention;

FIG. 4 is a view illustrating a structure of a dye-sensitized solar cell including metal oxide nanoparticles according to an exemplary embodiment of the present invention; and

FIG. 5 is a graph illustrating photocurrent density-voltage characteristics of the dye-sensitized solar cell including the metal oxide nanoparticles according to the present invention and a known dye-sensitized solar cell.

<Description of Reference Numerals Indicating
Primary Elements in the Drawines>

| 10, 11, 12: dispersion device having three rollers | |
|---|---|
| 13: scraper knife | |
| 14: metal oxide nanoparticle paste before dispersion | |
| 15: uniformly dispersed metal oxide nanoparticle paste | |
| 20: conductive electrode (first electrode) 21: substrate | |
| 22: conductive film | 23: metal oxide nanoparticle layer |
| 24: dye | 30: counter electrode (second electrode) |
| 31: substrate | 32: conductive film |
| 40: electrolyte | 50: adhesive |

### DETAILED DESCRIPTION OF THE EMBODIMENTS

An exemplary embodiment of the present invention provides a method of manufacturing an oxide electrode for a dye-sensitized solar cell including steps of (a) mixing metal oxide nanoparticles, a binder resin, and a solvent to prepare a metal oxide paste,

(b) adding the metal oxide paste to a miller and pulverizing the metal oxide nanoparticles to prepare a paste including the metal oxide nanoparticles uniformly dispersed therein, and

(c) coating the paste including the metal oxide nanoparticles dispersed therein on a conductive transparent substrate, performing a heat treatment of the resulting substrate, and adsorbing a dye thereto to manufacture the conductive electrode.

Another embodiment of the present invention provides a dye-sensitized solar cell including a conductive electrode (first electrode) that is manufactured by using the above-mentioned method and includes metal oxide nanoparticles having a size of 1 to 500 nm on which a dye is adsorbed,

a counter electrode (second electrode) including a conductive transparent substrate disposed opposite to the first electrode, and

an electrolyte charged in a space between the conductive electrode (first electrode) and the counter electrode (second electrode).

Hereinafter, the present invention will be described in detail.

The present invention relates to a method of further uniformly and regularly dispersing a nanoparticle paste of a metal oxide used in a dye-sensitized solar cell by using a miller capable of uniformly dispersing the paste during the manufacturing of the dye-sensitized solar cell in order to improve efficiency of the solar cell and to prevent the metal oxide nanoparticles from being agglomerated in the paste.

As long as the miller can uniformly disperse the paste, any miller may be used to uniformly disperse the paste. Examples of the miller include a 3-roll miller and a bead miller, and it is preferable to use the 3-roll miller.

That is, the miller used in the present invention functions to disperse the small agglomerated particles in the paste, and the size of metal oxide particles is not changed even though the particles pass through the miller.

Thus, in the present invention, after the metal oxide nanoparticle paste including the metal oxide nanoparticles, the binder resin, and the solvent is prepared, the paste is provided to the miller that is capable of uniformly dispersing the paste to evenly and uniformly pulverize the metal oxide nanoparticles to have a regular size, and accordingly a metal oxide nanoparticle paste including the metal oxide nanoparticles uniformly dispersed therein is prepared.

Hereinafter, a detailed description will be given of a method of manufacturing a metal oxide nanoparticle paste according to an exemplary embodiment of the present invention with reference to the accompanying drawings.

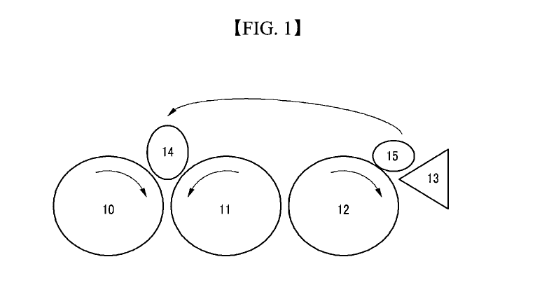

FIG. 1 is a view schematically illustrating a 3-roll miller according to an exemplary embodiment of the present invention.

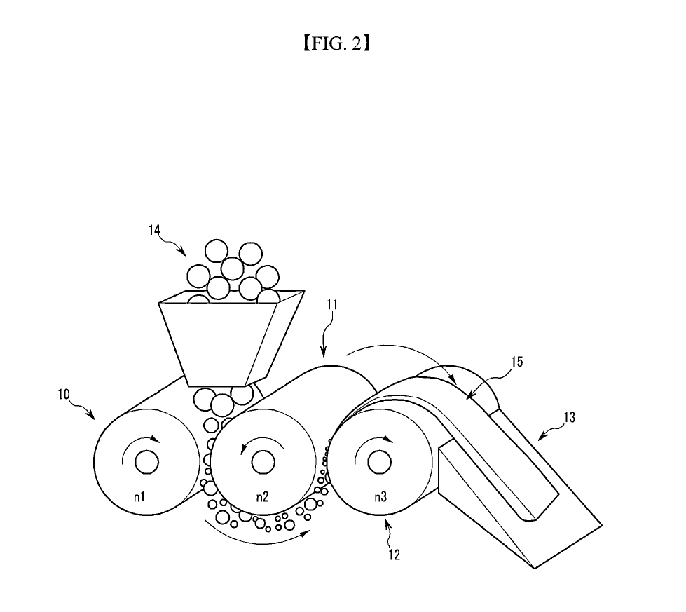

FIG. 2 is a view schematically illustrating dispersion of a metal oxide nanoparticle paste by using the 3-roll miller according to an exemplary embodiment of the present invention.

In connection with this, in FIG. 1, reference numerals 10 to 12 denote dispersion devices each including three rollers, reference numeral 13 denotes a scraper knife, reference numeral 14 denotes a metal oxide nanoparticle paste that is prepared before the dispersion is performed, and reference numeral 15 denotes a metal oxide nanoparticle paste in which metal oxide nanoparticles are pulverized and uniformly dispersed.

In the present invention, after the metal oxide nanoparticle paste including the solvent is prepared, the prepared metal oxide nanoparticle paste (reference numeral 14 of FIGS. 1 and 2) is provided to the 3-roll miller (reference numerals 10 to 12 of FIGS. 1 and 2) that rotates at a regular speed, wherein the three rollers are formed at predetermined intervals from each other.

While the oxide nanoparticle paste that is provided to the miller passes between rollers disposed at a narrow interval from each other, the agglomerated TiO₂ nanoparticles are pulverized in the oxide nanoparticle paste to evenly disperse and coat the metal oxide nanoparticles on the surfaces of the rollers.

The paste coated on the surfaces of the rollers is collected by a scraper knife (reference numeral 13 of FIGS. 1 and 2) after passing the final rollers (reference numeral 12 of FIGS. 1 and 2). The above-mentioned procedure may be repeated several times to obtain a paste including the metal oxide nanoparticles uniformly dispersed therein (reference numeral 15 of FIGS. 1 and 2).

In connection with this, if the interval between the rollers of the 3-roll miller is excessively larger than the size of a lump of the nanoparticles, it is difficult to expect the dispersion effect by the 3-roll miller.

In addition, if the pulverizing time is excessively long, the concentration of the final paste may vary because the solvent existing in the paste is evaporated.

Therefore, it is preferable for the interval between the rollers of the 3-roll miller that is used in the present invention to be in the range of 1 micron to 5 mm.

In addition, it is preferable for the pulverizing time of the 3-roll miller to be in the range of 1 minute to 2 hours.

Furthermore, the rotation speed of the rollers of the 3-roll miller should be in a range of 10 to 10,000 rpm to efficiently disperse the nanoparticles.

In order to prepare the metal oxide paste provided to the a bead miller or the 3-roll miller, the metal oxide nanoparticles are mixed with a solvent by using a process to prepare a colloidal solution having a viscosity of 3×10⁴ to 30×10⁵ cps, in which the metal oxide is dispersed, the solution is mixed with a binder resin, and the solvent is removed therefrom. The paste viscosity can be controlled by even the paste ingredients. However, it is preferable to optimize the viscosity of the paste by using a bead miller in order to improve the printing property in the manufacturing process of an electrode. In addition, if the paste viscosity is higher, a pudding phenomenon of the paste occurs due to a poor flow property of the paste, and the film after coating of the paste is peeled.

Additionally, in the present invention, the paste that is prepared by the dispersion process and includes the metal oxide nanoparticles dispersed therein is coated on the conductive transparent substrate and dried, and the dye is adsorbed thereto to manufacture a metal oxide conductive electrode.

In the present invention, the metal oxide nanoparticles 23 may be oxides of any one metal selected from the group consisting of Ti, Zr, Sr, Zn, In, Yr, La, V, Mo, W, Sn, Nb, Mg, Al, Y, Sc, Sm, and Ga, and complex oxides thereof.

More preferably, the metal oxide nanoparticles may be selected from the group consisting of titanium oxide (TiO₂), zinc oxide (ZnO), tin oxide (SnO₂), and tungsten oxide (WO₃).

With respect to the size of the metal oxide particles, their average particle size is preferably 500 nm or less and more preferably in the range of 1 to 500 nm.

In addition, the kind of binder resin is not particularly limited, and a general polymer that functions as a binder may be used.

Examples of the binder resin include ethyl cellulose, polyethylene glycol, and the like.

Any solvent may be used as long as the solvent is used to prepare a colloidal solution, and examples of the solvent include ethanol, methanol, terpineol, lauric acid, THF, water, and the like.

In the present invention, examples of the composition constituting the metal oxide nanoparticle paste may include a composition containing titanium oxide, terpineol, ethyl cellulose, and lauric acid, or a composition containing titanium oxide, ethanol, and ethyl cellulose.

Additionally, the conductive transparent substrate preferably includes a transparent plastic substrate or a glass substrate, and a material of the transparent plastic substrate is selected from the group consisting of polyethylene terephthalate (PET), polyethylene naphthalate (PEN), polycarbonate (PC), polypropylene (PP), polyimide (PI), and triacetyl cellulose (TAC).

Furthermore, it is preferable that a conductive film made of any one selected from the group consisting of indium tin oxide (ITO), fluorine tin oxide (FTO), ZnO—Ga₂O₃, Zno—Al₂O₃, and SnO₂—Sb₂O₃ is coated on either side of the conductive transparent substrate.

A first step of operating a dye-sensitized solar cell is a procedure for generating a photocharge from light energy.

Generally, a dye material is used to generate the photocharge, and it absorbs light that permeates the conductive transparent substrate and is excited.

Accordingly, the dye can be absorbed conductive particulates and a light scattering particle used to form the metal oxide nanoparticles or porous films, and the kind of dye is not limited as long as the dye absorbs visible rays so as to enable electrons to be excited.

Preferable examples of the dye include a Ru complex or a material containing an organic material that is capable of absorbing visible light. For example, Ru(4,4′-dicarboxy-2,2′-bipyridine)₂(NCS)₂ may be used.

With respect to the adsorption method of the dye, a method that is typically applied to the dye-sensitized solar cell may be used. For example, the first electrode on which the metal oxide nanoparticles are formed is dipped into a dispersion solution including the dye and then left for at least 12 hours to perform a natural adsorption process.

The kind of solvent that disperses the dye is not limited, but preferable examples of the solvent may be acetonitrile, dichloromethane, alcohol solvents, and so on.

After the dye is adsorbed, a process of washing the dye that is not adsorbed may be performed by using a solvent washing method.

When the metal oxide nanoparticles that are evenly dispersed by the 3-roll miller are coated on the conductive transparent substrate, a method such as a doctor blade or a screen printing method may be used, and a spin coating or spray coating method may be used to form a transparent film.

It is preferable that the heat treatment after the coating is performed under an air or oxygen atmosphere at a high temperature in the range of 450 to 500° C. for about 30 minutes.

Furthermore, the present invention provides a dye-sensitized solar cell prepared by using the conductive electrode including the metal oxide nanoparticles on which the dye is adsorbed.

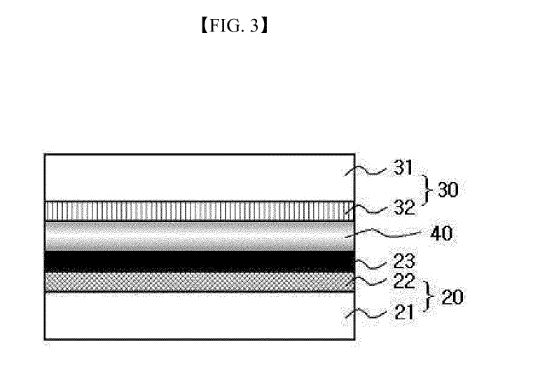

FIG. 3 is a cross-sectional view schematically illustrating a configuration of a dye-sensitized solar cell according to an exemplary embodiment of the present invention.

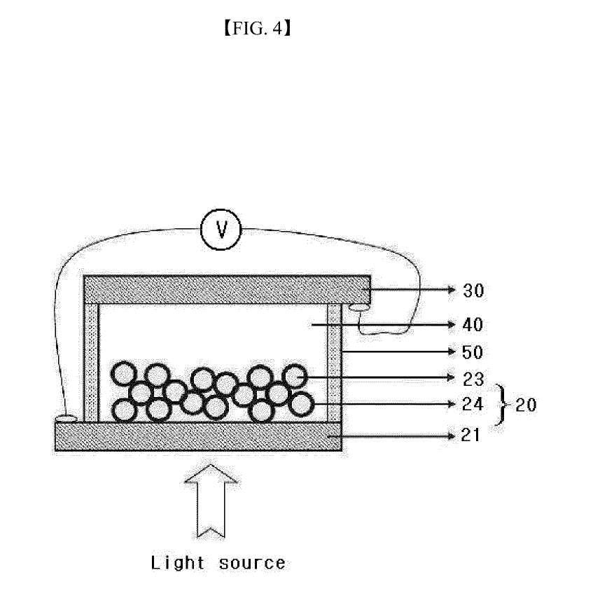

In addition, FIG. 4 is a view illustrating a structure of a dye-sensitized solar cell including metal oxide nanoparticles according to an exemplary embodiment of the present invention.

With reference to FIG. 3, the dye-sensitized solar cell of the present invention includes a conductive electrode 20 in which a conductive substrate 21, a conductive film 22, and a metal oxide nanoparticle layer 23 are sequentially layered, a counter electrode 30 in which a conductive substrate 31 disposed opposite to the conductive electrode 20 and a conductive film 32 are layered, and an electrolyte 40 between the conductive electrode 20 and the counter electrode 30, and the conductive electrode and the counter electrode are adhered to each other by an adhesive.

To be more specific, with reference to FIG. 4, a dye-sensitized solar cell according to an exemplary embodiment of the present invention includes a conductive electrode (first electrode) 20 that is manufactured by the above-mentioned method and includes the metal oxide nanoparticle layer 23 on which a dye 24 is adsorbed, the counter electrode (second electrode) 30 including a conductive transparent substrate disposed opposite to the first electrode 20, and an electrolyte 40 that is charged in a space between the first electrode 20 and the second electrode 30. They are adhered to each other by using an adhesive 50, and the metal oxide nanoparticles are dispersed by using the 3-roll miller to be uniformly dispersed on the conductive transparent substrate.

In this connection, in FIG. 3, reference numeral 30 denotes the counter electrode. For convenience, the substrate 31 and the conductive film 32 are not shown.

Additionally, the present invention may have the porous film formed on either side of the first electrode. In this case, the conductive particulate or the light scattering particle that is made of the same material as the porous film and has an average particle diameter of 150 nm or more may be added. Alternatively, both the conductive particulate and the light scattering particle may be added.

Preferably, the conductive transparent substrate of the first electrode and the second electrode includes a transparent plastic substrate or a glass substrate, and a material of the transparent plastic substrate is selected from the group consisting of polyethylene terephthalate (PET), polyethylene naphthalate (PEN), polycarbonate (PC), polypropylene (PP), polyimide (PI), and triacetyl cellulose (TAC).

It is preferable that in the first electrode 20, a conductive film made of any one selected from the group consisting of indium tin oxide (ITO), fluorine tin oxide (FTO), ZnO—Ga₂O₃, ZnO—Al₂O₃, and SnO₂—Sb₂O₃ is coated on either side of the conductive transparent substrate.

Preferably, in the second electrode 23, the first conductive film made of any one selected from the group consisting of indium tin oxide (ITO), fluorine tin oxide (FTO), ZnO—Ga₂O₃, ZnO—Al₂O₃, and SnO₂—Sb₂O₃ is coated on a side of the conductive transparent substrate, and the second conductive film comprising Pt or a noble metal material is coated on the first conductive film.

The metal coated on the second conductive film may be a material selected from the group consisting of Pt, Au, Ni, Cu, Ag, In, Ru, Pd, Rh, Ir, Os, C, a conductive polymer, or a combination thereof.

A typical iodine-based oxidation and reduction electrolyte may be used as the electrolyte 40, and a solution containing iodine dissolved in acetonitrile may be used. However, the kind of electrolyte is not limited thereto, and any electrolyte may be used without limitation as long as the electrolyte has a hole conduction function.

For example, the electrolyte functions to receive electrons from the counter electrode by using iodides/triodides due to oxidation and reduction, and to transfer the electrons to the dye. In connection with this, open circuit voltage depends on a difference between an energy level of the dye and an oxidation and reduction level of the electrolyte.

The electrolyte solution may be uniformly dispersed between the first electrode and the second electrode, and the metal oxide nanoparticles may be immersed therein.

The method of manufacturing the dye-sensitized solar cell according to an exemplary embodiment of the present invention includes steps of: adding the metal oxide nanoparticle paste (reference numeral 14 of FIGS. 1 and 2) to the 3-roll miller (reference numerals 10 to 12 of FIGS. 1 and 2) of FIG. 1 to prepare the uniformly dispersed paste (reference numeral 15 of FIGS. 1 and 2); coating the uniformly dispersed paste on a side of any one of a plurality of conductive films 22 coated on the conductive transparent substrate 21; sintering the resulting substrate at a high temperature; adsorbing the dye 24 to manufacture the conductive electrode (the first electrode plate) 20 containing the nanoparticle oxides 23; coating the nanoparticle metal conductive film 32 on the transparent conductive substrate 31; performing the heat treatment to manufacture the counter electrode (the second electrode plate) 30; adhering the first electrode plate to the second electrode plate by using the adhesive 50 so that the first electrode plate faces the second electrode plate; and injecting an electrolyte solution 40 between the nano-crystalline oxide film and the nanoparticle metal film that face each other after adhering the second electrode plate and the first electrode plate.

Additionally, the method of an exemplary embodiment of the present invention includes connecting a cathode and an anode of unit cells that are formed of the nano-crystalline oxide film and the nanoparticle metal film facing each other to each other through wires.

The formation of the conductive material on the transparent substrate of the first electrode and the second electrode may be performed by using a physical vapor deposition method such as sputtering and electron beam deposition.

With respect to the adhesive, one that is extensively known in the related art may be used, and examples thereof may include a thermoplastic polymer film, an epoxy resin, and the like.

The following will describe examples of the present invention. The present invention should not be construed as being limited to the following examples set forth herein; rather these examples are provided so that this disclosure will be thorough and complete, and will fully convey the concept of the invention to those skilled in the art.

### Example 1

### Preparation of the Paste Including Metal Oxide Nanoparticles Uniformly and Evenly Dispersed Therein

The titanium oxide nanoparticle paste was uniformly dispersed by using the 3-roll miller of FIG. 1.

Specifically, 3 g of the TiO₂ paste including titanium oxide having a particle size of 20 nm was prepared, and was then dispersed by using an EXAKT50 3-roll miller manufactured by EXAKT Co., Ltd. of Germany as shown in FIG. 1 for 20 minutes while the interval between the rollers was maintained to be 20 μm to prepare the metal oxide paste.

The rotation speed of the roller was 450 rpm.

TiO₂ having a particle size of 20 nm was mixed with ethanol used as a solvent to prepare a colloidal solution containing metal oxides dispersed therein and mixed with ethyl cellulose used as a binder resin, and the solvent was removed to prepare a TiO₂ paste according to a typical process.

Manufacturing of the Dye-Sensitized Solar Cell

The metal oxide nanoparticle paste was coated on FTO as a first transparent electrode by using a doctor blade method, and was subjected to heat treatment at 500° C. for 15 minutes to form a blocking layer and a titanium oxide nanostructure on the first transparent electrode.

The formed nanostructure was immersed in a 0.3 mM Ru(4,4′-dicarboxy-2,2′-bipyridine)₂(NCS)₂ dye solution dissolved in ethanol for 12 hours or more to adsorb the dye, thereby forming the first electrode layer.

H₂PtCl₆ was coated on the transparent electrode on which FTO was coated by using a spin coating process, and the heat treatment was then performed at 500° C. for 30 minutes to form the second electrode layer.

A thermoplastic polymer film having a thickness of 25 μm was disposed between the first electrode and the second electrode, and compressed at 100° C. for 15 seconds to adhere the two electrodes to each other.

Next, iodides/triodides were injected as the electrolyte to manufacture the solar cell, and its cell characteristics were measured.

The area of the solar cell was 0.1 to 0.3 cm².

### Comparative Example 1

A cell was manufactured by using the same method as in Example 1, except that the paste was not dispersed, and the cell characteristics were then measured.

### Experimental Example

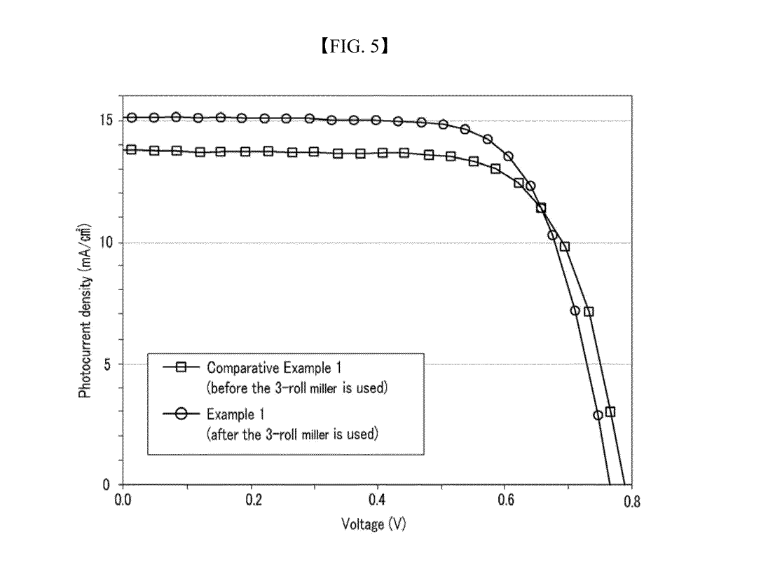

Photocurrent density-voltage characteristics were compared to each other for the solar cells of Example 1 and Comparative Example 1, and graphs thereof are shown in FIG. 5.

Furthermore, the photocurrent density (Jsc), the open circuit voltage (Voc), the charging coefficient (FF), and the energy conversion efficiency (Eff) that are important characteristics of the solar cell were measured, and the results are shown in Table 1.

TABLE 1

| | Jsc | Voc | FF | Eff |
|---|---|---|---|---|
| | (mA/cm²) | (V) | (%) | (%) |
| Comparative | 13.8 | 0.788 | 0.711 | 7.74 |
| Example 1 | | | | |
| (before the 3-roll | | | | |
| miller is used) | | | | |
| Example 1 | 15.2 | 0.768 | 0.707 | 8.15 |
| (after the 3-roll | | | | |
| miller is used) | | | | |

As shown in Table 1 and FIG. 5, it can be seen that the photocurrent density of the solar cell including the paste manufactured by using the 3-roll miller according to an exemplary embodiment of the present invention was increased, and thus energy conversion efficiency was increased.

The metal oxide paste according to an exemplary embodiment of the present invention is advantageous in that, since the metal oxide nanoparticles are evenly dispersed to have the regular size, the dye-sensitized solar cell has improved efficiency.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A method of manufacturing an oxide electrode for a dye-sensitized solar cell, the method comprising:
mixing metal oxide nanoparticles, a binder resin, and a solvent to prepare a metal oxide paste;
adding the metal oxide paste to a miller and pulverizing the metal oxide nanoparticles to prepare a paste including the metal oxide nanoparticles uniformly dispersed therein; and
coating the paste including the metal oxide nanoparticles dispersed therein on a conductive transparent substrate, performing a heat treatment of the resulting substrate, and adsorbing a dye thereon to manufacture the conductive electrode, wherein the miller is a bead miller, and the heat treatment after the coating is performed in an air or oxygen atmosphere at a high temperature in a range of 450 to 500° C. for 30 minutes,
wherein the metal oxide paste has a viscosity of 3×10⁴ to 30×10⁵ cps.

2. The method of claim 1, wherein the metal oxide nanoparticles include oxides of any one metal selected from the group consisting of Ti, Zr, Sr, Zn, In, Yr, La, V, Mo, W, Sn, Nb, Mg, Al, Y, Sc, Sm, and Ga, and complex oxides thereof.

3. The method of claim 1, wherein a size of each of the metal oxide nanoparticles is 1 to 500 nm.

4. The method of claim 1, wherein the binder resin is selected from the group consisting of ethyl cellulose and polyethylene glycol.

5. The method of claim 1, wherein the solvent is selected from the group consisting of ethanol, methanol, THF, and water.

6. The method of claim 1, wherein the conductive transparent substrate includes a transparent plastic substrate selected from the group consisting of polyethylene terephthalate (PET), polyethylene naphthalate (PEN), polycarbonate (PC), polypropylene (PP), polyimide (PI), and triacetyl cellulose (TAG), or a glass substrate.

7. The method of claim 1, wherein a conductive film of any one selected from the group consisting of indium tin oxide (ITO), fluorine tin oxide (FTO), ZnO—Ga₂CO₃, ZnO—Al₂O₃, and SnO₂—Sb₂O₃ is coated on only one side of the conductive transparent substrate.

8. The method of claim 1, wherein the dye includes a material containing a Ru complex or an organic material to absorb visible light.

9. A dye-sensitized solar cell comprising:
a conductive electrode that is manufactured by the method according to claim 1 and that includes metal oxide nanoparticles having a size in a range of 1 to 500 nm on which a dye is adsorbed;
a counter electrode comprising a conductive transparent substrate disposed opposite to the conductive electrode; and
an electrolyte charged in a space between the conductive electrode and the counter electrode.

10. The dye-sensitized solar cell of claim 14, wherein in the counter electrode, a first conductive film that is made of any one selected from the group consisting of indium tin oxide (ITO), fluorine tin oxide (FTO), ZnO—Ga₂O₃, ZnO—Al₂O₃), and SnOa-SbiCb is coated on only one side of the conductive transparent substrate, and a second conductive film including Pt or a noble metal material is coated on the first conductive film.
